(19) United States
(12) Patent Application Publication
(10) Pub. No.: US 2002/0187608 A1
(43) Pub. Date: Dec. 12, 2002

(54) Method of forming a floating gate of a non-volatile memory device

(76) Inventor: Horng-Huei Tseng, Hsinchu (TW)

Correspondence Address: Chun M. Ng, BLAKELY, SOKOLOFF, TAYLOR & ZAFMAN LLP, Seventh Floor, 12400 Wilshire Boulevard, Los Angeles, CA, 90025-1026, US

(21) Appl. No.: 09/815,997

(22) Filed: Mar. 22, 2001

(51) Int. Cl. H01L 21/336

(52) U.S. Cl. 438/257; 438/593

(57) ABSTRACT

A method of forming a floating gate of a non-volatile memory device is disclosed. First, a gate dielectric layer and a first polysilicon layer are formed on a semiconductor substrate. After forming a first dielectric layer on the first polysilicon layer, the first dielectric layer is patterned to form an opening. After that, a recess with sloped sidewalls is formed in the first polysilicon layer by partially etching the first polysilicon layer through the opening. Next, a top silicon oxide is formed by performing a thermal oxidation process. After removing the first dielectric layer, a floating gate with sharp corners is formed by performing an anisotropical etching process to etch an exposed portion of the first polysilicon layer using the top silicon oxide as an etching mask.

### BACKGROUND OF THE INVENTION

(1) Field of the Invention

The present invention relates generally to a method of manufacturing a non-volatile memory device, and more particularly, to a method of forming a floating gate of a non-volatile memory device.

(2) Description of the Related Art

Integrated circuits (ICs), such as ultra-large scale integrated (ULSI) circuits, can include as many as one billion transistors or more. The ULSI circuits are generally composed of complementary metal oxide semiconductor field effect transistors (MOSFETs). For a typical random access memory (RAM), the data stored in the memory is volatile. For this reason, a power supply is needed to refresh the data stored in the memory.

On the other hand, non-volatile memories such as Read-only-memories (ROMs), electrically erasable programmable ROM (EEPEOM) or flash memories, are memories into which information is permanently stored.

In order to reduce the production cost and enhance the manufacture yield of a non-volatile memory device, it is important to develop a single-transistor electrically programmable and erasable memory device. For this reason, a method for forming a single transistor non-volatile electrically alterable semiconductor memory device was disclosed in U.S. Pat. No. 5,029,130. According to this prior art, referring first to FIG. 1A, a first insulating layer 12 is formed on a silicon substrate 10. Thereafter, a polysilicon layer 14 and a silicon nitride layer 16 are formed on the first insulating layer 12. After that, the silicon nitride layer 16 is next patterned by performing conventional photolithographic and etching process to form an opening 18.

Referring now to FIG. 1B, a thermal oxidation process (like conventional LOCOS scheme) is performed to form an oxide layer 20 in the opening 18. As shown in FIG. 1B, the silicon nitride layer 16 is partially lifted during the thermal oxidation process because of the bird's beak effect. Next, the silicon nitride layer 16 is removed by performing a wet etching process, as shown in FIG. 1C

Referring now to FIG. 1D, an anisotropic etching process is applied to selectively etch the exposed polysilicon layer 14 which is not directly beneath the oxide layer 20. A floating gate 22 with sharp curved-up portion is thus formed, as shown in FIG. 1D.

Referring now to FIG. 1E, a thermal oxide layer 24 is grown to a certain thickness over the floating gate 22. Thereafter, nitridization of the oxide layer 24 is performed by thermally annealing the oxide layer 24 with dilute NH₃ using N₂ or Ar as a carrier gas at an elevated temperature; e.g., greater than 800° C. This will result in the formation of an oxynitride film. Finally, a second polysilicon layer 26 is deposited over the oxynitride layer 24. The second polysilicon layer 26 is going to be patterned to form the control gate of the non-volatile memory cell.

However, the application of conventional LOCOS scheme in this prior art has a fundamental limitation, which is the “thinning” of the thermal oxide in narrow regions. This thinning effect occurs due to the high stresses generated during the growth of the oxide in narrow openings. For this reason, this prior art results in oxide encroachment and field oxide thinning.

### SUMMARY OF THE INVENTION

Accordingly, it is a primary object of the present invention to a method of manufacturing a floating gate of a non-volatile memory device.

It is another object of the present invention to provide a floating gate of a non-volatile memory device.

It is further another object of the present invention to provide a method of forming a gate structure having sharp corners.

A method of forming a floating gate of a non-volatile memory device is disclosed. First, a gate dielectric layer and a first polysilicon layer are formed on a semiconductor substrate. After forming a first dielectric layer on the first polysilicon layer, the first dielectric layer is patterned by the conventional photolithographic and anisotropic etching schedule to form an opening. After that, a recess with sloped sidewalls is formed in the first polysilicon layer by partially etching the first polysilicon layer through the opening. The partial etching process can be performed by either a wet etching process or a dry etching process. According to the present invention, the sidewalls of the recess have a slope ranged from 40 to 80 degree with respect to a horizontal plane.

Next, a top silicon oxide is formed by performing a thermal oxidation process. After removing the first dielectric layer, a floating gate with sharp corners is formed by performing an anisotropical etching process to etch an exposed portion of the first polysilicon layer using the top silicon oxide as an etching mask. After that, a tunneling dielectric layer is formed over the floating gate. Finally, a control gate of the non-volatile memory cell is formed on the tunneling dielectric layer.

The key feature of the present invention is that the floating gate having sharp corners is formed by a thermal oxidation process followed by a partial etching process to form a recess with sloped sidewall in the first polysilicon layer. For this reason, the bird's beak of the top silicon oxide is shorter, and especially a less oxide-thinning effect is also achieved. Therefore, the thickness of the top silicon oxide has much better uniformity all over the substrate according to the present invention.

### BRIER DESCRIPTION OF THE DRAWINGS

The accompanying drawings forming a material part of this description, in which

FIG. 1A to FIG. 1E schematically illustrate the cross-sectional diagram of the method of forming a single transistor non-volatile electrically alterable semiconductor memory device according to the prior art.

FIG. 2A to FIG. 2G schematically illustrate the cross-sectional diagram of the method of forming a non-volatile memory cell according to the first embodiment of the present invention.

FIG. 3A to FIG. 3G schematically illustrate the cross-sectional diagram of the method of forming a non-volatile memory cell according to the second embodiment of the present invention.

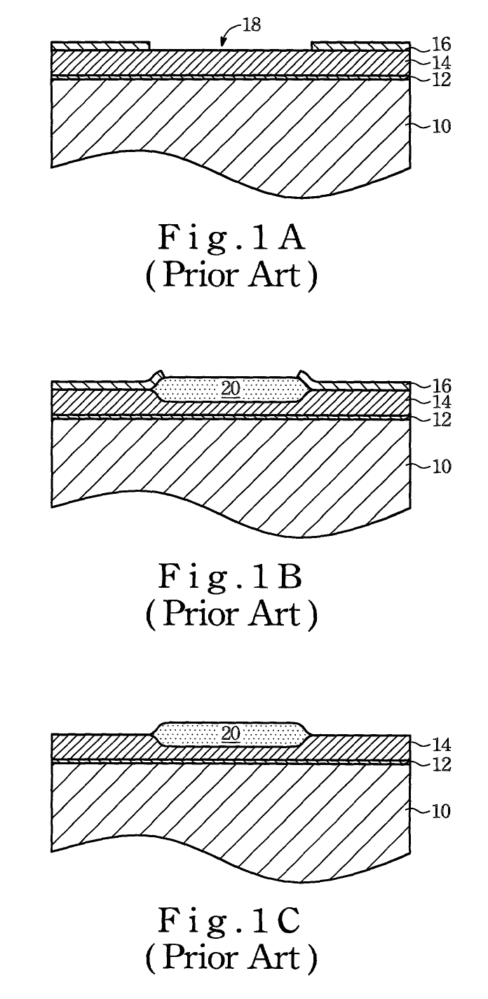

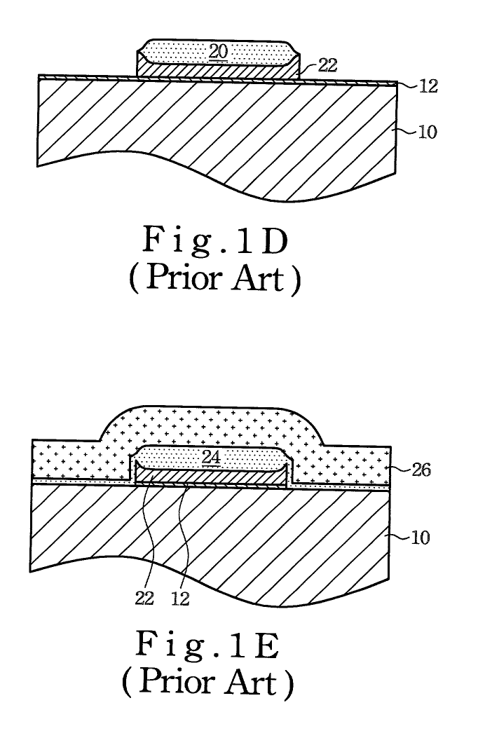

### DESCRIPTION OF THE PREFERRED EMBODIMENTS

The present invention relates generally to a method of manufacturing a non-volatile memory device, and more particularly, to a method of forming a floating gate of a non-volatile memory device.

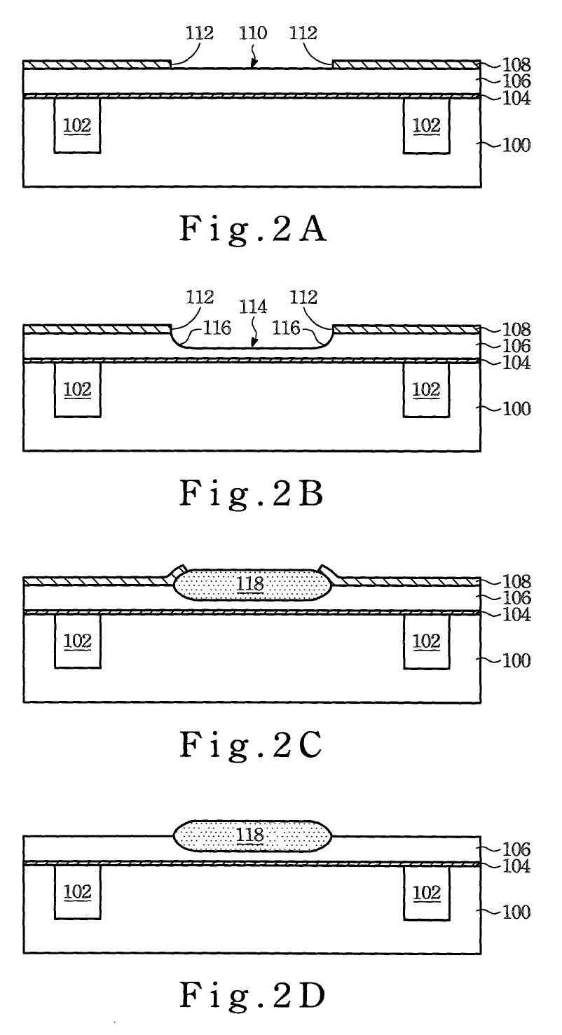

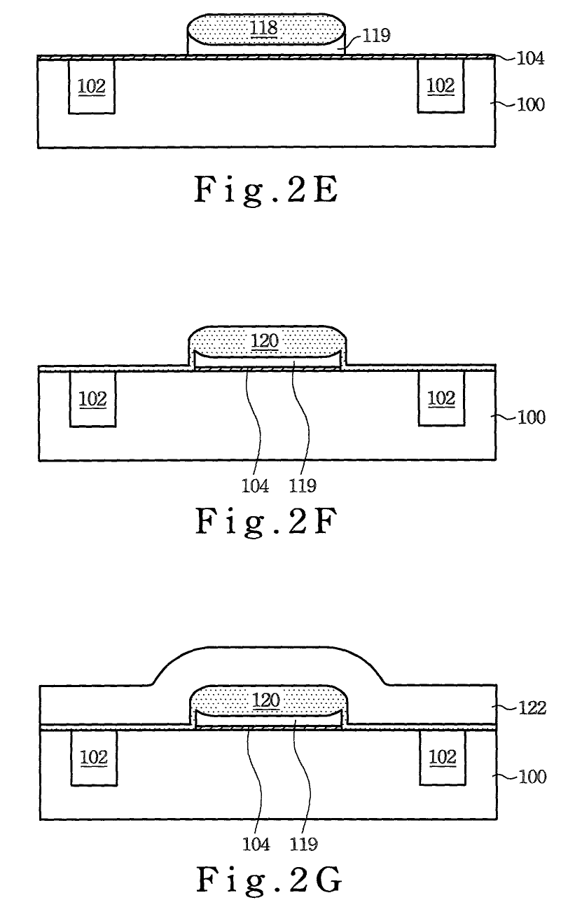

According to the first embodiment of the present invention, referring first to FIG. 2A, a semiconductor substrate 100 comprised of P-type single crystalline silicon is provided. Shallow trench isolation regions (STI) 102 are next formed in the semiconductor substrate 100, and the active region is also defined. After that, a gate dielectric layer 104, a first polysilicon layer 106, and a first dielectric layer 108 are formed on the semiconductor substrate 100 in sequence. Thereafter, an opening 110 for defining a floating gate of the non-volatile memory cell is formed by patterning the first dielectric layer 108. During the patterning procedure, the conventional photolithographic process and anisotropic etching process are applied. Because the opening 110 is formed by means of the anisotropic etching process, the sidewalls 112 of the opening 110 are nearly vertical.

The shallow trench isolation regions 102 are formed by first forming shallow trenches in the semiconductor substrate 100 using the conventional photolithographic and anisotropic reactive ion etching (RIE) procedures. After removal of the photoresist shape used to define the shallow trenches, a silicon oxide layer is deposited by low-pressure chemical vapor deposition (LPCVD) or plasma enhanced chemical vapor deposition (PECVD) procedures for completely filling the shallow trenches. A chemical mechanical polishing (CMP) process is then performed to remove silicon oxide from the top surface of the semiconductor substrate 100. The gate dielectric layer 104 is formed by conventional deposition process such as thermal oxidation, PECVD or LPCVD to a thickness between 70 Angstroms to 200 Angstroms. The gate dielectric layer 104 is composed of silicon dioxide (SiO₂), silicon nitride, or silicon oxynitride. The first polysilicon layer 106 is deposited by a low-pressure CVD (LPCVD) process or a plasma-enhanced CVD (PECVD) process to a thickness between 500 Angstroms to 3000 Angstroms. The first dielectric layer 108 is composed of silicon nitride or silicon oxynitride.

Referring now to FIG. 2B, the key feature of the present invention is shown. A recess 114 in the first polysilicon layer 106 with sloped sidewalls 116 is formed by partially etching the first polysilicon layer 106 through the opening 110. The partial etching process can be performed by either a wet etching process or a dry etching process. According to the present invention, the sidewalls of the recess have a slope ranged from 40 to 80 degree with respect to a horizontal plane.

Referring now to FIG. 2C, a thermal oxidation process is applied to form a top silicon oxide 118 in the recess 114. Because the original recess 114 in the first polysilicon layer 106 has sloped sidewalls 116, the top silicon oxide 118 formed by using the thermal oxidation process has a shorter bird's beak and less oxide thinning. For this reason, the thickness of the top silicon oxide 118 has better uniformity all over the substrate 100.

After that, the first dielectric layer 108 is removed by performing a wet etching process using hot phosphoric acid, as shown in FIG. 2D.

Referring now to FIG. 2E, a floating gate 119 of the non-volatile memory cell is formed by performing an anisotropical etching process to etch an exposed portion of the first polysilicon layer 106. During the anisotropical etching process, the top silicon oxide 118 serves as an etching mask. The floating gate 119 formed in this step has sharp corners which will have efficient electron injection between the floating gate and the control gate in the non-volatile memory cell.

Thereafter, a tunneling dielectric layer 120 is formed by first depositing a dielectric layer and then patterning the dielectric layer by traditional photolithographic process and anisotropic etching process, as shown in FIG. 2F. The tunneling dielectric layer 120 is composed of silicon oxide, silicon nitride, oxide/nitride composition film, or oxide/nitride/oxide composition film (ONO). Next, a control gate 122 is formed by first depositing a second silicon layer and then patterning the second silicon layer by traditional photolithographic process and anisotropical etching process, as shown in FIG. 2G.

The key feature of the present invention is that the floating gate having sharp corners is formed by a thermal oxidation process followed by a partial etching process to form a recess with sloped sidewall in the first polysilicon layer. For this reason, the bird's beak of the top silicon oxide is shorter, and especially a less oxide-thinning effect is achieved. Therefore, the thickness of the top silicon oxide 118 has better uniformity all over the substrate according to the present invention.

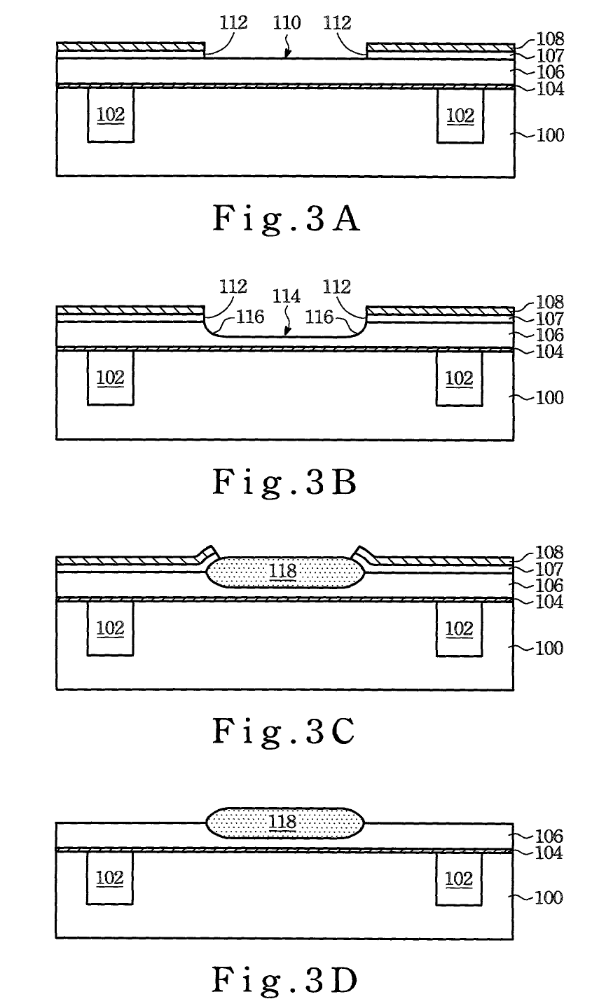

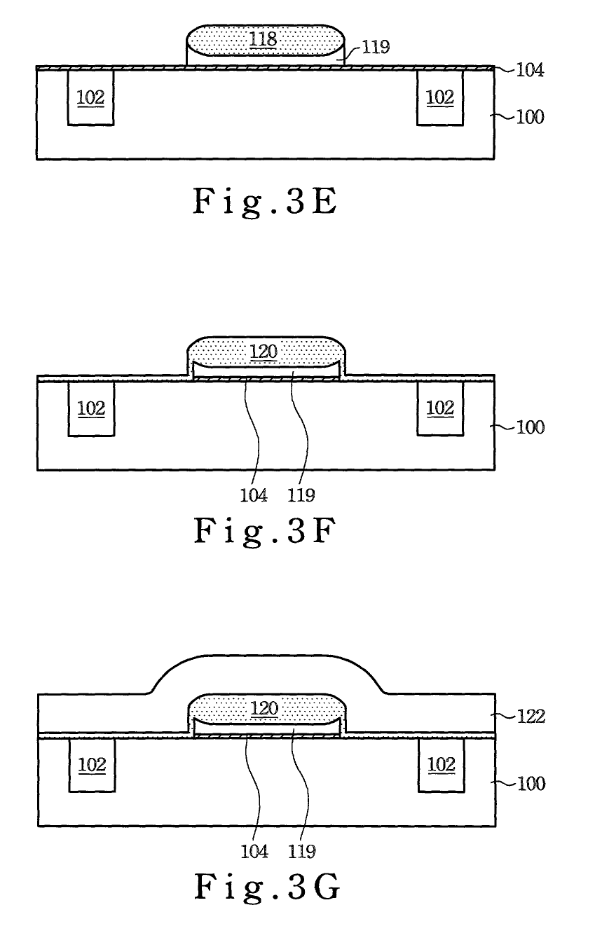

According to the second embodiment of the present invention, referring first to FIG. 3A, a semiconductor substrate 100 comprised of P-type single crystalline silicon is provided. Shallow trench isolation regions (STI) 102 are next formed in the semiconductor substrate 100, and the active region is also defined. After that, a gate dielectric layer 104, a first polysilicon layer 106, a buffer layer 107, and a first dielectric layer 108 are formed on the semiconductor substrate 100 in sequence. Thereafter, an opening 110 for defining a floating gate of the non-volatile memory cell is formed by patterning the first dielectric layer 108 and the buffer layer 107. During the patterning procedure, the conventional photolithographic process and anisotropic etching process are applied. Because the opening 110 is formed by means of the anisotropic etching process, the sidewalls 112 of the opening 110 are nearly vertical.

The gate dielectric layer 104 is formed by conventional deposition process such as thermal oxidation, PECVD or LPCVD to a thickness between 70 Angstroms to 200 Angstroms. The gate dielectric layer 104 is composed of silicon dioxide (SiO₂), silicon nitride, or silicon oxynitride. The first polysilicon layer 106 is deposited by a low-pressure CVD (LPCVD) process or a plasma-enhanced CVD (PECVD) process to a thickness between 500 Angstroms to 3000 Angstroms. The buffer layer 107 is generally an oxide layer, and deposited by a low-pressure CVD (LPCVD) process or a plasma-enhanced CVD (PECVD) process to a thickness between 200 Angstroms to 500 Angstroms. The first dielectric layer 108 is composed of silicon nitride or silicon oxynitride.

Referring now to FIG. 3B, the key feature of the present invention is shown. A recess 114 in the first polysilicon layer 106 with sloped sidewalls 116 is formed by partially etching the first polysilicon layer 106 through the opening 110. The partial etching process can be performed by either a wet etching process or a dry etching process. According to the present embodiment, the sidewalls of the recess have a slope ranged from 40 to 80 degree with respect to a horizontal plane.

Referring now to FIG. 3C, a thermal oxidation process is applied to form a top silicon oxide 118 in the recess 114. Because the original recess 114 in the first polysilicon layer 106 has sloped sidewalls 116, the top silicon oxide 118 formed by using the thermal oxidation process has a shorter bird's beak and less oxide thinning. For this reason, the thickness of the top silicon oxide 118 has better uniformity all over the substrate 100.

After that, the first dielectric layer 108 is removed by performing a wet etching process using hot phosphoric acid. Next, the buffer layer 107 is removed by performing a wet etching process using HF solution, as shown in FIG. 3D.

Referring now to FIG. 3E, a floating gate 119 of the non-volatile memory cell is formed by performing an anisotropical etching process to etch an exposed portion of the first polysilicon layer 106. During the anisotropical etching process, the top silicon oxide 118 serves as an etching mask. The floating gate 119 formed in this step has sharp corners which will have efficient electron injection between the floating gate and the control gate in the non-volatile memory cell.

Thereafter, a tunneling dielectric layer 120 is formed by first depositing a dielectric layer and then patterning the dielectric layer by traditional photolithographic process and anisotropic etching process, as shown in FIG. 3F. The tunneling dielectric layer 120 is composed of silicon oxide, silicon nitride, oxide/nitride composition film, or oxide/nitride/oxide composition film (ONO). Next, a control gate 122 is formed by first depositing a second silicon layer and then patterning the second silicon layer by traditional photolithographic process and anisotropical etching process, as shown in FIG. 3G.

The key feature of the present invention is that the floating gate having sharp corners is formed by a thermal oxidation process followed by a partial etching process to form a recess with sloped sidewall in the first polysilicon layer. For this reason, the bird's beak of the top silicon oxide is shorter, and especially a less oxide-thinning effect is achieved. Therefore, the thickness of the top silicon oxide 118 has better uniformity all over the substrate according to the present invention.

It should be understood that the foregoing relates to only preferred embodiments of the present invention, and that it is intended to cover all changes and modifications of the embodiments of the invention herein used for the purposes of the disclosure, which do not constitute departures from the spirit and scope of the invention.

[image]

[image]

What we claimed is:

1. A method of forming a floating gate of a non-volatile memory device, said method comprising:
a. forming a gate dielectric layer and a first polysilicon layer on a semiconductor substrate;
b. forming a first dielectric layer on said first polysilicon layer;
c. patterning said first dielectric layer to form an opening;
d. forming a recess with sloped sidewalls in said first polysilicon layer by partially etching said first polysilicon layer through said opening;
e. forming a top silicon oxide by performing a thermal oxidation process;
f. removing said first dielectric layer; and
g. forming said floating gate with sharp corners by performing an anisotropical etching process to etch an exposed portion of said first polysilicon layer using said top silicon oxide as an etching mask.

2. The method of claim 1, after forming said first polysilicon layer, further comprising forming a buffer layer on said first polysilicon layer.

3. The method of claim 2, wherein said buffer layer is composed of silicon oxide.

4. The method of claim 1, wherein said first dielectric layer is composed of silicon nitride.

5. The method of claim 1, wherein said first dielectric layer is composed of silicon oxynitride.

6. The method of claim 1, wherein said gate dielectric layer is composed of silicon nitride.

7. The method of claim 1, wherein said gate dielectric layer is composed of silicon oxynitride.

8. The method of claim 1, wherein said recess with sloped sidewalls in said first polysilicon layer is formed by partially etching said first polysilicon layer through said opening by means of a wet etching step.

9. The method of claim 1, wherein said recess with sloped sidewalls in said first polysilicon layer is formed by partially etching said first polysilicon layer through said opening by means of a dry etching step.

10. The method of claim 1, wherein said sidewalls of said recess have a slope ranged from 40 to 80 degree with respect to a horizontal plane.

11. The method of claim 1, wherein said first dielectric layer is removed by performing a wet etching process using hot phosphoric acid.

12. The method of claim 1, after forming said floating gate further comprising:
a. forming a tunneling dielectric layer over said floating gate; and
b. forming a control gate of said non-volatile memory cell on said tunneling dielectric layer.

13. The method of claim 12, wherein said tunneling dielectric layer is formed by first depositing a dielectric layer and then patterning said dielectric layer by conventional photolithography process and etching process.

14. The method of claim 13, wherein said dielectric layer is an oxide/nitride composition film.

15. The method of claim 13, wherein said dielectric layer is an oxide/nitride/oxide composition film (ONO).

16. The method of claim 12, wherein said control gate is formed by first depositing a second polysilicon layer and then patterning said second polysilicon layer.

17. A method of forming a gate structure with sharp corners, said method comprising:
a. forming a gate dielectric layer and a polysilicon layer on a semiconductor substrate;
b. forming a first dielectric layer on said polysilicon layer;
c. patterning said first dielectric layer to form an opening;
d. forming a recess with sloped sidewalls in said polysilicon layer by partially etching said polysilicon layer through said opening;
e. forming a top silicon oxide by performing a thermal oxidation process;
f. removing said first dielectric layer; and
g. forming said gate structure with sharp corners by performing an anisotropical etching process to etch an exposed portion of said polysilicon layer using said top silicon oxide as an etching mask.

18. The method of claim 17, wherein said recess with sloped sidewalls in said polysilicon layer is formed by partially etching said polysilicon layer through said opening by means of a dry etching step.

19. The method of claim 17, wherein said sidewalls of said recess have a slope ranged from 40 to 80 degree with respect to a horizontal plane.

20. The method of claim 17, wherein said first dielectric layer is removed by performing a wet etching process using hot phosphoric acid.
